(19) United States
(12) Patent Application Publication
(10) Pub. No.: US 2014/0252207 A1
(43) Pub. Date: Sep. 11, 2014

(54) ANALOG-TO-DIGITAL CONVERTER AND SOLID-STATE IMAGING DEVICE

(71) Applicant: Kabushiki Kaisha Toshiba, Minato-ku (JP)

(72) Inventor: Ryuta OKAMOTO, Yokohama-shi (JP)

(73) Assignee: Kabushiki Kaisha Toshiba, Minato-ku (JP)

(21) Appl. No.: 14/193,370

(22) Filed: Feb. 28, 2014

(30) Foreign Application Priority Data
Mar. 11, 2013 (JP) 2013-048209

(51) Int. Cl. H03M 1/12; H04N 5/357

(52) U.S. Cl. CPC H03M 1/12; H04N 5/357
USPC 250/208.1; 341/172

(57) ABSTRACT

An ADC includes a comparator and first and second amplifier circuits including a fully-differential operational amplifier. The comparator converts an analog signal output from the operational amplifier into digital data. The first amplifier circuit stores charge corresponding to a signal having a phase reverse to an input signal in each of a pair of capacitors during a first period and transfers the charge in one of the pair of capacitors to the other via the operational amplifier during a second period to amplify the reversed phase signal twofold. The second amplifier circuit amplifies the input signal twofold similarly to the first amplifier circuit.

### CROSS-REFERENCE TO RELATED APPLICATIONS

This application is based upon and claims the benefit of priority from Japanese Patent Application No. 2013-048209, filed on Mar. 11, 2013; the entire contents of which are incorporated herein by reference.

### FIELD

Embodiments described herein relate generally to an analog-to-digital converter and a solid-state imaging device.

### BACKGROUND

A solid-state imaging device such as a complementary metal oxide semiconductor (CMOS) area sensor in related art includes a column-parallel analog-to-digital converter configured to convert analog pixel signals read in units of rows from a pixel unit in which multiple photoelectric conversion devices are arranged in a matrix into digital data.

The column-parallel analog-to-digital converter includes an ADC group in which one analog-to-digital converter (hereinafter referred to as an “ADC”) is arranged for each column of the photoelectric conversion devices. A high-resolution cyclic ADC is known as an ADC for the solid-state imaging device.

The cyclic ADC typically samples an input analog signal by using capacitors, then determines the magnitude of the signal sampled by using an operational amplifier by a comparator, and performs twofold amplification while resampling a signal obtained by subtracting a certain value by using the capacitors. Furthermore, the cyclic ADC repeats a series of operation of determining the magnitude of the signal resampled by using the operational amplifier, performing twofold amplification while subtracting a certain value, and resampling the resulting signal by the capacitors.

In solid-state imaging devices, the number of pixels has been increasing and the size of pixels has been getting smaller in recent years. On the other hand, improvement in the quality of images captured by solid-state imaging devices is desired. An ADC for a solid-state imaging device capable of improving the signal to noise (S/N) ratio (signal to noise ratio) while suppressing an increase in the circuit size is therefore desired.

### BRIEF DESCRIPTION OF THE DRAWINGS

FIG. 1 is an explanatory diagram illustrating a CMOS area sensor including an ADC according to an embodiment;

FIG. 2 is an explanatory diagram illustrating an example of a circuit configuration of the ADC according to the embodiment;

FIGS. 3 to 14 are explanatory diagrams illustrating examples of operating states of the ADC according to the embodiment; and

FIG. 15 is an explanatory diagram illustrating an example of a circuit configuration of the ADC according to a modified example of the embodiment.

### DETAILED DESCRIPTION

According to an embodiment, an analog-to-digital converter is provided. The analog-to-digital converter includes a comparator, a first amplifier circuit, and a second amplifier circuit. The comparator compares an analog signal voltage output from a fully-differential operational amplifier including a non-inverting input, an inverting input, an inverted output, and a non-inverted output with a predetermined threshold and converts the analog signal voltage to digital data. The first amplifier circuit stores electric charge corresponding to a signal having a phase reverse to that of the input signal to be converted by the comparator in each of a pair of capacitors during a first period and transfers the charge from one of the pair of capacitors to the other via the non-inverting input and the inverted output of the operational amplifier during a second period to amplify the reversed phase signal twofold. The second amplifier circuit stores electric charge corresponding to the input signal in each of a pair of capacitors during the first period and transfers the charge from one of the pair of capacitors to the other via the inverting input and the non-inverted output of the operational amplifier during the second period to amplify the input signal twofold.

A solid-state imaging device including an analog-to-digital converter (hereinafter referred to as an “ADC”) according to the embodiment will be described in detail below with reference to the accompanying drawings. Note that the embodiment does not limit the present invention. Although a CMOS area sensor will be described as an example of the solid-state imaging device according to the embodiment, the solid-state imaging device according to the embodiment may be any image sensor other than the CMOS area sensor.

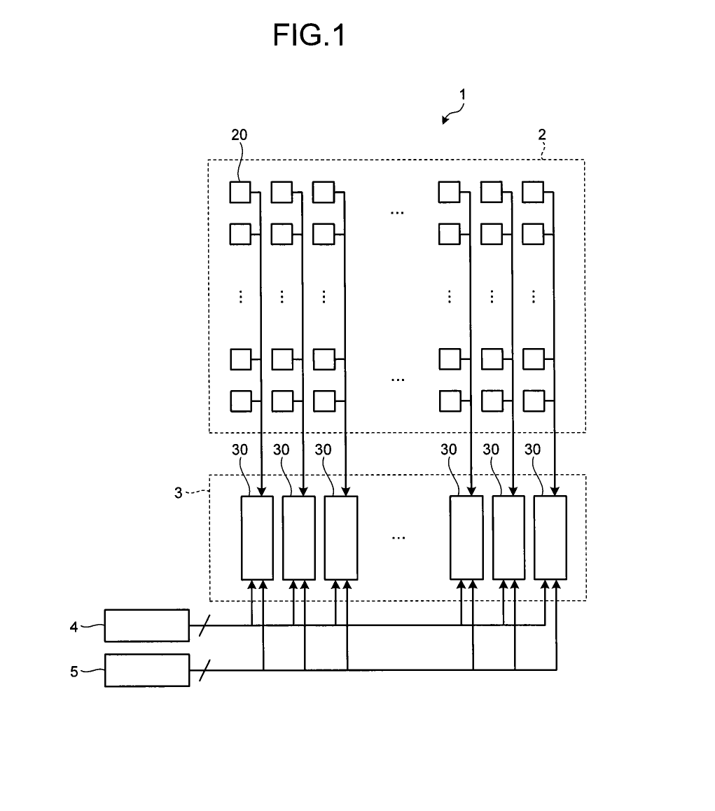

FIG. 1 is an explanatory diagram illustrating a CMOS area sensor 1 including an ADC 30 according to the embodiment. Note that FIG. 1 selectively illustrates components necessary for description of the ADC 30 according to the embodiment, but does not illustrate other components included in a typical CMOS area sensor.

As illustrated in FIG. 1, the CMOS area sensor 1 includes a pixel unit 2, an ADC group 3, a switch control signal generator 4, and a bias voltage generator 5. The pixel unit 2 includes multiple photoelectric conversion devices 20 configured to perform photoelectric conversion to convert incident light into an amount of charge corresponding to received light intensity and store the charge.

The photoelectric conversion devices 20 are arranged in a matrix each in association with a pixel in a captured image. The charges stored by the photoelectric conversion devices 20 are sequentially selected in units of rows of the photoelectric conversion devices 20 in the pixel unit 2 and output in the form of analog pixel signals to the ADC group 3.

The ADC group 3 is a column-parallel analog-to-digital converter including multiple ADCs 30 each provided for one column of the photoelectric conversion devices 20 in the pixel unit 2. The ADC group 3 sequentially converts analog pixel signals input in units of rows of the photoelectric conversion devices 20 from the pixel unit 2 into digital data.

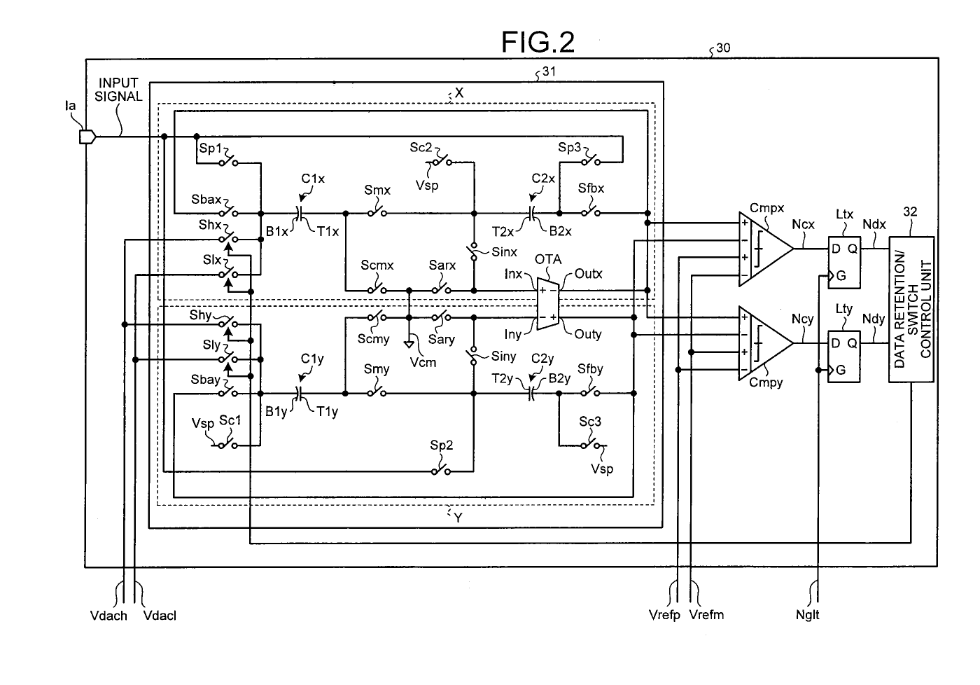

Specifically, the respective ADCs 30 convert analog pixel signals (hereinafter referred to as “input signals”) input from the photoelectric conversion devices 20 of the respective associated columns in parallel. An example of a specific circuit configuration of the ADCs 30 will be described later with reference to FIG. 2.

The switch control signal generator 4 is a processing unit configured to output control signals to switch multiple switches of the ADCs 30 on/off. The bias voltage generator 5 is a processing unit configured to apply a reference voltage that is referred to when input signals are converted to digital data by the ADCs 30 to the ADCs 30.

Next, the example of the specific circuit configuration of the ADCs 30 according to the embodiment will be described with reference to FIG. 2. FIG. 2 is an explanatory diagram illustrating the example of the circuit configuration of the ADCs 30 according to the embodiment. As illustrated in FIG. 2, an ADC 30 includes an input unit 1a to which an input signal is input from the pixel unit 2, an amplifier/subtractor 31, a pair of differential comparators Cmpx and Cmpy, a pair of latches Ltx and Lty, and a data retention/switch control unit 32.

The amplifier/subtractor 31 is a processing unit configured to output a signal obtained by amplifying an input signal and subtracting a predetermined value therefrom to the differential comparators Cmpx and Cmpy. The amplifier/subtractor 31 includes a differential operational amplifier OTA, a first amplifier circuit X, and a second amplifier circuit Y.

The operational amplifier OTA includes a non-inverting input Inx, an inverting input Iny, an inverted output Outx, and a non-inverted output Outy, and outputs signals according to the difference between the non-inverting input Inx and the inverting input Iny to the inverted output Outx and the non-inverted output Outy.

The first amplifier circuit X and the second amplifier circuit Y are provided to have a symmetric, fully-differential structure with the operational amplifier OTA therebetween. The first amplifier circuit stores electric charge determined by a signal having a phase reverse to that of the input signal in a first capacitor C1x and a second capacitor C2x during a first period. Subsequently, the first amplifier circuit transfers the charge in the first capacitor C1x to the second capacitor C2x by using the operational amplifier OTA during a second period. Note that the first capacitor C1x and the second capacitor C2x have an equal capacitance and an equal charging voltage, and the amounts of charge stored in the first capacitor C1x and the second capacitor C2x are thus equal. Thus, the amount of charge stored in the second capacitor C2x is doubled as a result of transferring the charge in the first capacitor C1x to the second capacitor C2x.

In the meantime, the second amplifier circuit Y stores electric charge determined by the input signal in a third capacitor C1y and a fourth capacitor C2y during the first period. Subsequently, the second amplifier circuit transfers the charge in the third capacitor C1y to the fourth capacitor C2y by using the operational amplifier OTA during the second period. Note that the third capacitor C1y and the fourth capacitor C2y have an equal capacitance and an equal charging voltage, and the amounts of charge stored in the third capacitor C1y and the fourth capacitor C2y are thus equal. Thus, the amount of charge stored in the fourth capacitor C2y is doubled as a result of transferring the charge in the third capacitor C1y to the fourth capacitor C2y.

According to the amplifier/subtractor 31, electric charge determined by an input signal is stored in the four capacitors C1x, C2x, C1y, and C2y during the first period, and the charge in the first capacitor C1x and the third capacitor C1y is transferred to the second capacitor C2x and the fourth capacitor C2y by using the operational amplifier OTA during the second period, which results in doubling the charge stored in each of the second capacitor C2x and the fourth capacitor C2y.

Thus, the difference in amplitude between the signal output from the inverted output Outx and the signal output from the non-inverted output Outy of the operational amplifier OTA is four times the amplitude of the input signal. In other words, the input signal can be amplified fourfold during the second period according to the amplifier/subtractor 31.

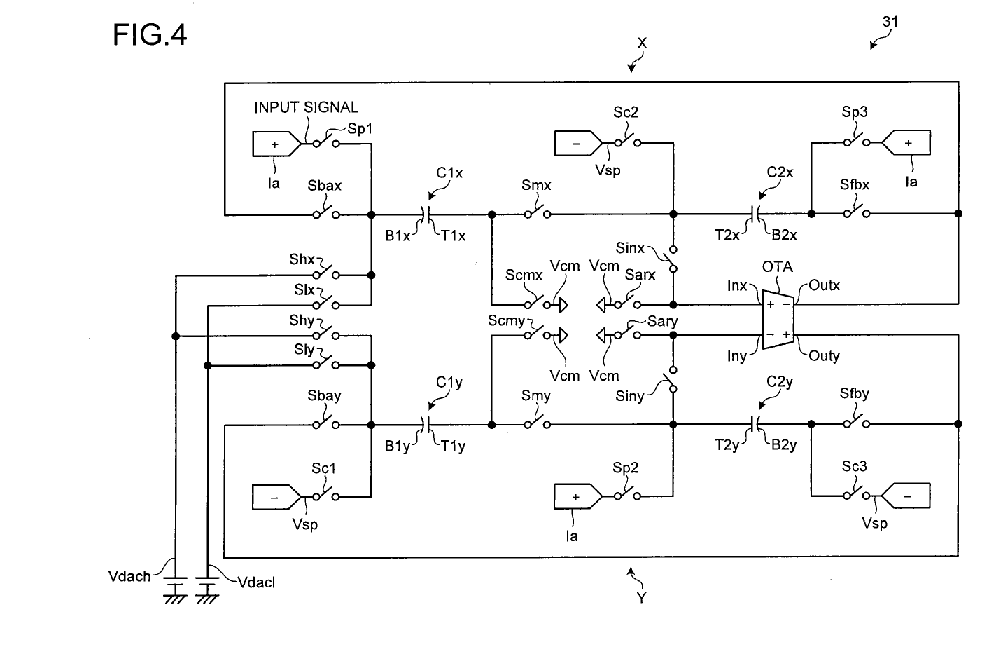

Subsequently, the amplifier/subtractor 31 performs amplification/subtraction process of sequentially amplifying the signals output from the inverted output Outx and the non-inverted output Outy of the operational amplifier OTA twofold whereas inputting charge corresponding to the signals to the non-inverting input Inx and the inverting input Iny. A specific example of operation of the amplifier/subtractor 31 will be described later with reference to FIGS. 4 to 14.

As described above, the ADCs 30 first amplify input signals fourfold during the first period instead of amplifying signals twofold as in the related art. As a result, on the assumption that the amount of noise generated after the first amplification during the first period does not vary during the second and subsequent periods, the ADCs 30 can improve the S/N ratio since S (the signal quantity) of the S/N ratio is quadrupled instead of being doubled as in the related art.

The example of the circuit configuration of the ADCs 30 will be described more specifically below. The first amplifier circuit X of the amplifier/subtractor 31 includes the first capacitor C1x and the second capacitor C2x, and the second amplifier circuit Y thereof includes the third capacitor C1y and the fourth capacitor C2y. These first capacitor C1x, second capacitor C2x, third capacitor C1y, and fourth capacitor C2y are used for signal sampling and amplification.

Note that an upper electrode T1x of the first capacitor C1x and an upper electrode T2x of the second capacitor C2x are connected via a switch Smx. A predetermined reference voltage Vsp is applied to a connection line connecting the switch Smx and the upper electrode T2x of the second capacitor C2x by the bias voltage generator 5 (see FIG. 1) via a switch Sc2.

Furthermore, the connection line connecting the switch Smx and the upper electrode T2x of the second capacitor C2x is connected to the non-inverting input Inx of the operational amplifier OTA via a switch Sinx. A predetermined reference voltage Vcm is applied to the non-inverting input Inx by the bias voltage generator 5 via a switch Sarx. The reference voltage Vcm is also applied to the upper electrode T1x of the first capacitor C1x via a switch Scmx.

The inverted output Outx of the operational amplifier OTA is also connected with a lower electrode B1x of the first capacitor C1x via a switch Sbax, and with a lower electrode B2x of the second capacitor C2x via a switch Sfbx.

The lower electrode B1x of the first capacitor C1x is also connected with the input unit Ia via a switch Sp1. Furthermore, control voltages Vdach, Vdacl to suppress the voltage of the signal output from the inverted output Outx of the operational amplifier OTA within a predetermined range are applied to the lower electrode B1x of the first capacitor C1x via switches Shx and Slx, respectively. Note that the predetermined range is such a range of voltage at the inverted output Outx and the non-inverted output Outy that the performance of the operational amplifier OTA can be maintained.

The control voltages Vdach and Vdacl are selected by using the switches Shx and Slx depending on digital data retained by the data retention/switch control unit 32 and applied to the first capacitor C1x and the second capacitor C2x. The control voltages Vdach and Vdacl are always constant.

Furthermore, the lower electrode B1x of the first capacitor C1x is connected with the lower electrode B2x of the second capacitor C2x via the switches Sbax and Sfbx. The lower electrode B2x of the second capacitor C2x is also connected with the input unit 1a via a switch Sp3.

In addition, an upper electrode T1y of the third capacitor C1y and an upper electrode T2y of the fourth capacitor C2y are connected via a switch Smy. An input signal from the input unit Ia is input to a connection line connecting the switch Smy and the upper electrode T2y of the fourth capacitor C2y via a switch Sp2.

Furthermore, the connection line connecting the switch Smy and the upper electrode T2y of the fourth capacitor C2y is connected to the non-inverting input Inx of the operational amplifier OTA via a switch Siny. The predetermined reference voltage Vcm is applied to the non-inverting input Iny by the bias voltage generator 5 (see FIG. 1) via a switch Sary. The reference voltage Vcm is also applied to the upper electrode T1y of the third capacitor C1y via a switch Scmy.

The non-inverted output Outy of the operational amplifier OTA is also connected with a lower electrode B1y of the third capacitor C1y via a switch Sbay, and with a lower electrode B2y of the fourth capacitor C2y via a switch Sfby.

Furthermore, the predetermined reference voltage Vsp is applied to the lower electrode B1y of the third capacitor C1y by the bias voltage generator 5 (see FIG. 1) via a switch Sc1. Still further, the control voltages Vdach, Vdacl to suppress the voltage of the signal output from the non-inverted output Outy of the operational amplifier OTA within a predetermined range are applied to the lower electrode B1y of the third capacitor C1y via switches Shy and Sly, respectively. Note that the predetermined range is such a range of voltage at the inverted output Outx and the non-inverted output Outy that the performance of the operational amplifier OTA can be maintained.

Furthermore, the lower electrode B1y of the third capacitor C1y is connected with the lower electrode B2y of the fourth capacitor C2y via the switches Sbay and Sfby. The predetermined reference voltage Vsp is applied to the lower electrode B2y of the fourth capacitor C2y by the bias voltage generator 5 (see FIG. 1) via a switch Sc3.

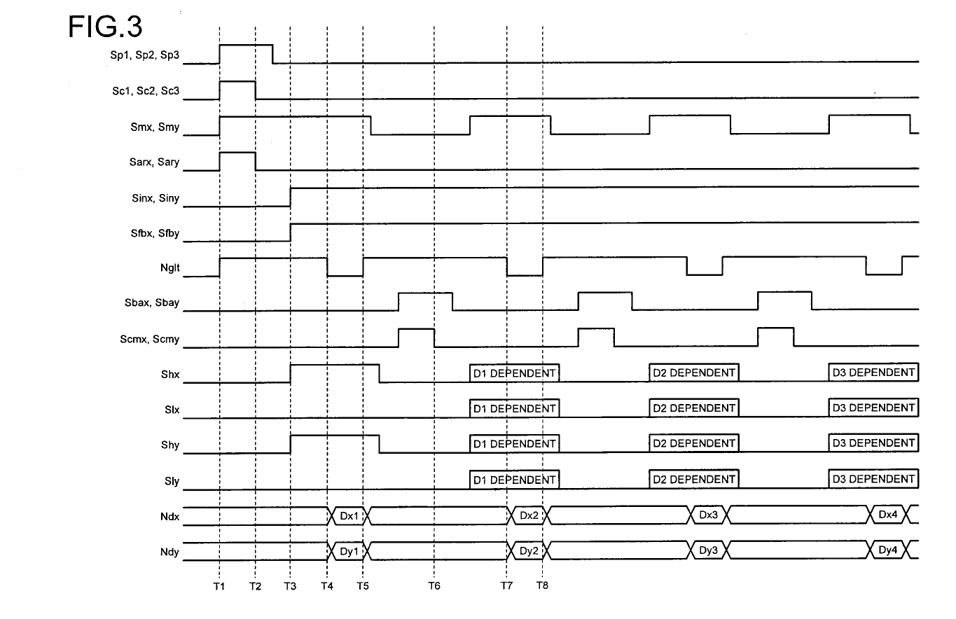

As described above, the amplifier/subtractor 31 has a fully-differential structure. This allows the amplifier/subtractor 31 to conduct common-mode rejection of external noise mixed in an input signal with the same phase. Operation of the amplifier/subtractor 31 will be described later with reference to FIGS. 3 to 14.

The differential comparator Cmpx compares a difference between signals input from the inverted output Outx and the non-inverted output Outy of the operational amplifier OTA with a difference (a predetermined threshold) obtained by subtracting a predetermined reference voltage Vrefm from a predetermined reference voltage Vrefp input from the bias voltage generator 5.

The differential comparator Cmpy compares a difference between signals input from the inverted output Outx and the non-inverted output Outy of the operational amplifier OTA with a difference (a predetermined threshold) obtained by subtracting the reference voltage Vrefp from the reference voltage Vrefm input from the bias voltage generator 5.

The differential comparators Cmpx and Cmpy then converts the comparison results to a high-level signal or a low-level signal, which are digital data representing the results, and outputs the signals to flip-flops Ltx and Lty, respectively. Specifically, each of the differential comparators Cmpx and Cmpy outputs a high-level signal if a result to be converted is larger than the predetermined threshold or outputs a low-level signal if a result to be converted is smaller than the predetermined threshold.

The latch Ltx holds an output Ncx from the differential comparator Cmpx from when a control signal Nglt input from a predetermined controller (not illustrated) is switched from high level to low level until the control signal is then switched to high level. The latch Ltx then outputs the held output Ncx as data Ndx to the data retention/switch control unit 32.

In the meantime, the latch Lty holds an output Ncy from the differential comparator Cmpy from when the control signal Nglt input from the predetermined controller (not illustrated) is switched from high level to low level until the control signal is then switched to high level. The latch Lty then outputs the held output Ncy as data Ndy to the data retention/switch control unit 32.

The data retention/switch control unit 32 functions to control the switches Shx, Slx, Shy, and Sly so as to selectively apply the control voltages Vdach and Vdacl for suppressing the voltages of the signals output from the inverted output Outx and the non-inverted output Outy of the operational amplifier OTA within the predetermined range to the first amplifier circuit X and the second amplifier circuit Y on the basis of the digital data obtained by the conversion by the differential comparators Cmpx and Cmpy.

The data retention/switch control unit 32 is a circuit that holds the data Ndx and Ndy input from the latches Ltx and Lty, and controls the switches Shx, Slx, Shy, and Sly to apply either of the control voltages Vdach and Vdacl to suppress the voltage values of the output signals from the operational amplifier OTA to be smaller than a predetermined voltage on the basis of the held data.

The data retention/switch control unit 32 then applies the control voltage to voltage control terminals of the switches Shx and Shy and voltage control terminals of the switches Slx and Sly. The data retention/switch control unit 32 further outputs control signals to switch ON/OFF the switches Shx, Slx, Shy, and Sly when data Ndx and Ndy to be held next are generated according to the data Ndx and Ndy last converted by the differential comparators Cmpx and Cmpy.

Note that the switches Sp1, Sp2, Sp3, Sc1, Sc2, Sc3, Smx, Smy, Sarx, Sary, Sinx, Siny, Sfbx, Sfby, Sbax, Sbay, Scmx, and Scmy other than the switches Shx, Slx, Shy, and Sly are switched ON/OFF on the basis of control signals input from the switch control signal generator 4.

When an input signal is to be subjected to cyclic analog-to-digital conversion (hereinafter referred to as “cyclic A/D conversion”), the ADC 30 amplifies the input signal fourfold while subtracting a certain value therefrom at the first cyclic A/D conversion, and amplifies the signal obtained by the subtraction twofold while subtracting a certain value therefrom at the second cyclic A/D conversion to convert the input signal to digital data.

As a result, on the assumption that noise caused after the first signal amplification does not vary, the signal to be converted by the ADC 30 is doubled as compared to a typical cyclic ADC of the related art that amplifies an input signal twofold every time. Thus, according to the ADC 30, the S/N ratio can be improved as compared to the typical cyclic ADC of the related art.

Furthermore, the ADCs 30 can have the fully-differential structure as described above, which allows common-mode rejection of external noise mixed in an input signal. Moreover, the number of capacitors included in the ADC 30 is four, which are the first capacitor C1x, the second capacitor C2x, the third capacitor C1y, and the fourth capacitor C2y.

The number of capacitors is the minimum required number of capacitors for amplifying a signal twofold and allowing fully-differential operation even if an input signal is not to be amplified fourfold at the first amplification.

Specifically, for amplifying a signal twofold and allowing fully-differential operation, two circuits configured to amplify a signal twofold are required, for example. In this case, each circuit configured to amplify a signal twofold amplifies an input signal twofold by holding a signal charge of the signal by one capacitor, copying the held signal charge to the other capacitor at the same time, and adding the charges held by the capacitors.

Hence, such a circuit requires at least two capacitors. For fully-differential operation, the number of the circuits required is two. Thus, at least a total of four capacitors are required. As described above, at least four capacitors are required for amplifying a signal twofold and allowing fully-differential operation even if an input signal is not to be amplified fourfold at the first amplification.

In contrast, the ADC 30 can amplify an input signal fourfold, and then amplify a signal twofold and allow fully-differential operation to remove external noise from the input signal by using the four capacitors described above without additionally providing capacitors to quadruple the input signal. With the ADCs 30, it is therefore possible to improve the S/N ratio while suppressing an increase in the circuit size.

Next, operation of an ADC 30 according to the embodiment will be described with reference to FIGS. 3 to 14. FIG. 3 illustrates timing charts of an example of operation of the ADC 30 according to the embodiment, and FIGS. 4 to 14 are explanatory diagrams illustrating examples of operating states of the ADC 30 according to the embodiment.

Note that FIGS. 4 to 14 illustrate a circuit equivalent to the amplifier/subtractor 31 illustrated in FIG. 2. In the following description, components illustrated in FIGS. 4 to 14 that are the same as those in the configuration illustrated FIG. 2 will be designated by the same reference numerals as those in FIG. 2 and the description thereof will not be repeated.

Timing charts for Ndx and Ndy illustrated in FIG. 3 indicate timing at which digital data are held by the data retention/switch control unit 32, and a timing chart for the control signal Nglt indicates the signal level of the control signal Nglt.

Furthermore, timing charts other than those for Ndx and Ndy indicate the signal levels of control signals that switch ON/OFF associated switches Sp1, Sp2, Sp3, Sc1, Sc2, Sc3, Smx, Smy, Sarx, Sary, Sinx, Siny, Sfbx, Sfby, Sbax, Sbay, Scmx, Scmy, Shx, Slx, Shy, and Sly.

As illustrated in FIG. 3, at a point before time T1, control signals for all of the switches Sp1, Sp2, Sp3, Sc1, Sc2, Sc3, Smx, Smy, Sarx, Sary, Sinx, Siny, Sfbx, Sfby, Sbax, Sbay, Shx, Slx, Shy, and Sly are low level.

During this period, all of the switches Sp1, Sp2, Sp3, Sc1, Sc2, Sc3, Smx, Smy, Sarx, Sary, Sinx, Siny, Sfbx, Sfby, Sbax, Sbay, Scmx, Scmy, Shx, Slx, Shy, and Sly are OFF in the amplifier/subtractor 31 as illustrated in FIG. 4.

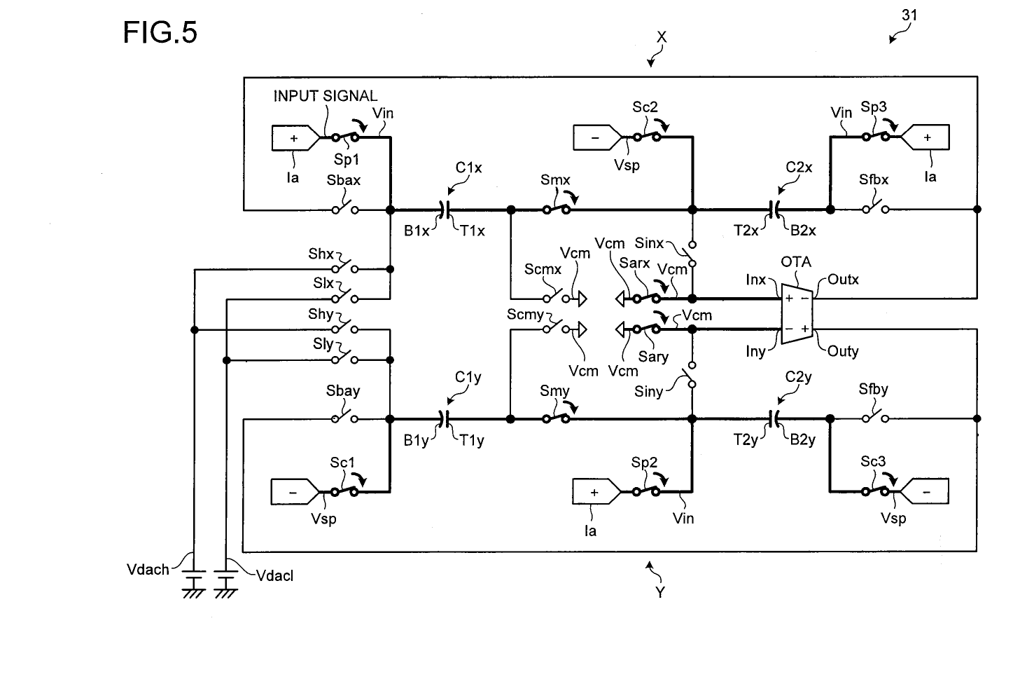

Then, as illustrated in FIG. 3, the amplifier/subtractor 31 switches the control signal Nglt to high level and switches control signals for the switches Sp1, Sp2, Sp3, Sc1, Sc2, Sc3, Smx, Smy, Sarx, and Sary to high level at time Ti. As a result, the switches Sp1, Sp2, Sp3, Sc1, Sc2, Sc3, Smx, Smy, Sarx, and Sary are turned ON as illustrated in FIG. 5.

In this state, the reference voltage Vsp is applied to the upper electrodes T1x and T2x of the first capacitor C1x and the second capacitor C2x, and a pixel output, that is, the voltage of the input signal (hereinafter referred to as “input voltage Vin”) is applied to the lower electrodes B1x and B2x. In the meantime, the input voltage Vin is applied to the upper electrodes T1y and T2y of the third capacitor C1y and the fourth capacitor C2y, and the reference voltage Vsp is applied to the lower electrodes B1y and B2y.

If it is assumed that all of the capacitances of the first capacitor C1x, the second capacitor C2x, the third capacitor C1y, and the fourth capacitor C2y are C, charge corresponding to C(Vsp−Vin) is stored in the first capacitor C1x and the second capacitor C2x. In addition, charge corresponding to C(Vin−Vsp) is stored in the third capacitor C1y and the fourth capacitor C2y.

Furthermore, the reference voltage Vcm is applied to the non-inverting input Inx and the inverting input Iny of the operational amplifier OTA. Note that the operational amplifier OTA is controlled so that the average of the inverted output Outx and the non-inverted output Outy is around the reference voltage Vcm. It is assumed that the amplification factor and the input resistance of the operational amplifier OTA are very large.

Subsequently, the amplifier/subtractor 31 switches the control signals for the switches Sc1, Sc2, Sc3, Sarx, and Sary to low level at time T2 and the switches Sc1, Sc2, Sc3, Sarx, and Sary are thus turned OFF as illustrated in FIG. 3.

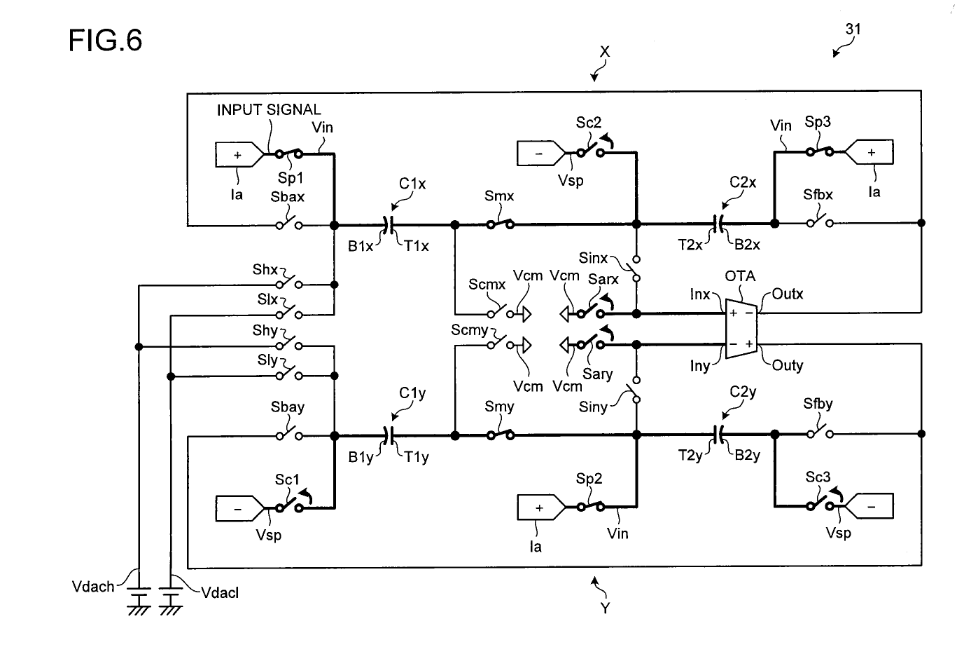

As a result, the charge corresponding to C(Vsp−Vin) is held (sampled) in the first capacitor C1x and the second capacitor C2x as illustrated in FIG. 6. In this manner, a signal having a phase reverse to that of the input signal is held by the first capacitor C1x and the second capacitor C2x by holding the signal charge of the input signal in the two capacitor units.

In addition, charge corresponding to C(Vin−Vsp) is held (sampled) in the third capacitor C1y and the fourth capacitor C2y. In this manner, a signal having a phase reverse to that of the input signal is held by the third capacitor C1y and the fourth capacitor C2y by holding the signal charge of the input signal in the two capacitor units. Furthermore, the reference voltage Vcm is held at the non-inverting input Inx and the inverting input Iny of the operational amplifier OTA.

In this manner, the switches Sc1, Sc2, Sc3, Sarx, and Sary on the side of the reference voltages Vsp and Vcm are first OFF, which is called bottom sampling, to suppress generation of noise caused by switching.

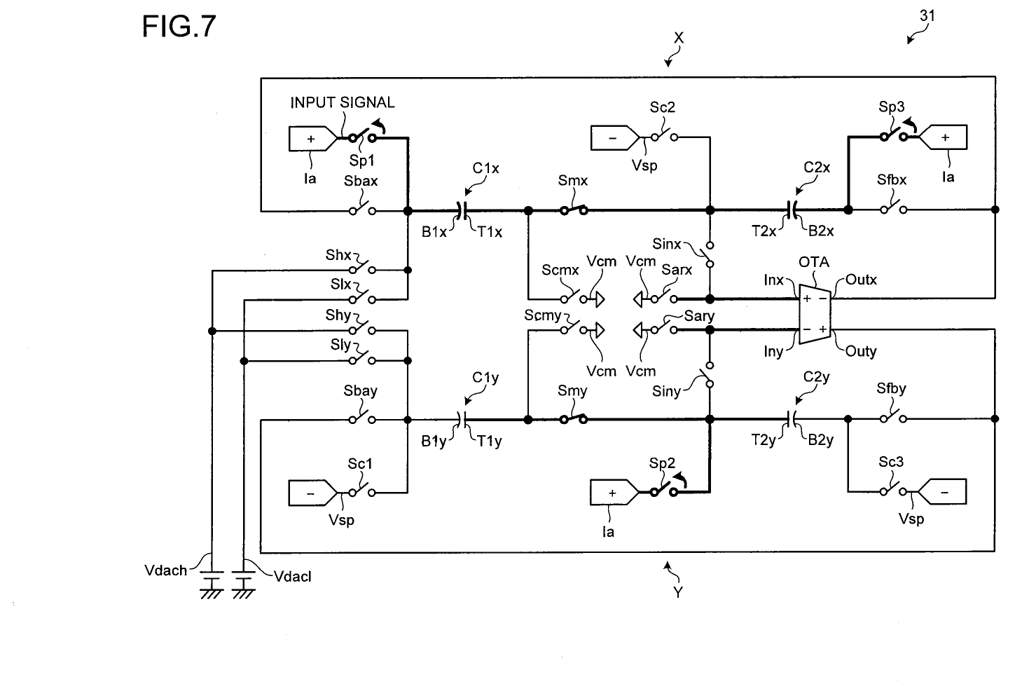

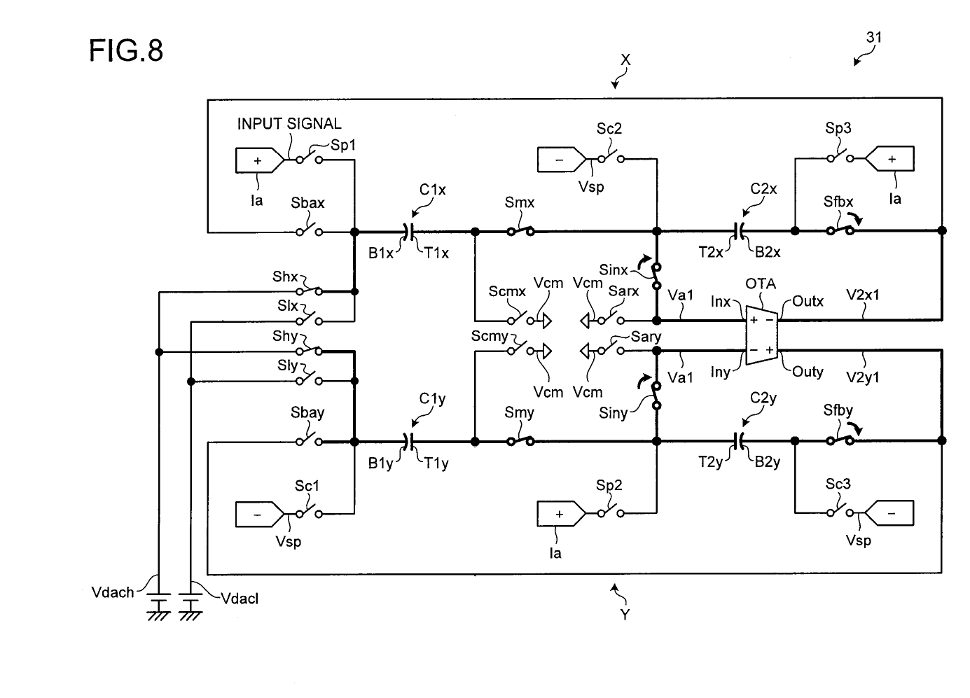

Subsequently, the amplifier/subtractor 31 switches control signals for the switches Sp1, Sp2, and Sp3 to low level as illustrated in FIG. 3, and the Sp1, Sp2, and Sp3 are thus turned OFF as illustrated in FIG. 7. Furthermore, the amplifier/subtractor 31 switches control signals for the switches Shx, Shy, Sinx, Siny, Sfbx, and Sfby to high level at time T3, and the switches Shx, Shy, Sinx, Siny, Sfbx, and Sfby are thus turned ON as illustrated in FIG. 8.

As a result, the signal having a phase reverse to that of the input signal held in the first capacitor C1x is input to the non-inverting input Inx of the operational amplifier OTA. In addition, the input signal held in the third capacitor C1y is input to the inverting input Iny of the operational amplifier OTA.

At this point, a negative feedback is applied to the non-inverting input Inx and the inverting input Iny of the operational amplifier OTA, and at time T4 after a certain time period, the voltages of the non-inverting input Inx and the inverting input Iny become substantially equal. This voltage is represented by Va1.

At this point, the voltage Va1 is applied to the upper electrode T1x of the first capacitor C1x and the upper electrode T1y of the third capacitor C1y, and the control voltage Vdach is applied to the lower electrode B1x of the first capacitor C1x and the lower electrode B1y of the third capacitor C1y. As a result, the charge held in the first capacitor C1x and the third capacitor C1y becomes C(Va1−Vdach).

In addition, the voltage Va1 is applied to the upper electrode T2x of the second capacitor C2x and the upper electrode T2y of the fourth capacitor C2y. When the voltage of the lower electrode B2x of the second capacitor C2x is represented by V2x1, the charge stored in the second capacitor C2x is C(Va1−V2x1). When the voltage of the lower electrode B2y of the fourth capacitor C2y is represented by V2y1, the charge stored in the fourth capacitor C2y is C(Va1−V2y1).

Since the sum of the charges in the first capacitor C1x, the second capacitor C2x, the third capacitor C1y, and the fourth capacitor C2y is maintained at time T2 and time T4 according to the law of charge conservation, the following equations are satisfied:

C(Vsp−Vin)+C(Vsp−Vin)=C(Va1−Vdach)+C(Va1−V2x1) Equation (1),

C(Vin−Vsp)+C(Vin−Vsp)=C(Va1−Vdach)+C(Va1−V2y1) Equation (2).

The difference between Equation (1) and Equation (2) is:

4C(Vsp−Vin)=C(−V2x1+V2y1) Equation (3),

and modification of Equation (3) results in:

V2x1−V2y1=4(Vin−Vsp) Equation (4).

The Equation (4) shows that the difference between V2x1 and V2y1 is four times the difference between the input voltage Vin and the reference voltage Vsp.

In this manner, the input signal is amplified fourfold by amplifying the input signal twofold and outputting the amplified signal to the non-inverting input Inx of the operational amplifier OTA by the first amplifier circuit X and amplifying the signal having a phase reverse to that of the input signal twofold and outputting the amplified signal to the inverting input Iny of the operational amplifier OTA by the second amplifier circuit Y.

Furthermore, since the operational amplifier OTA is controlled so that the average of V2x1 and V2y1 becomes Vcm,

(V2x1+V2y1)/2=Vcm Equation (5) is satisfied,

and combination with Equation (4) results in:

V2x1=Vcm+2(Vin−Vsp) Equation (6), and

V2y1=Vcm−2(Vin−Vsp) Equation (7).

Here, the reference voltages Vrefp and Vrefm for the differential comparators Cmpx and Cmpy are represented by Vcm+Vref/8 and Vcm−Vref/8, respectively. The differential comparator Cmpx outputs a high-level output Ncx when the difference between V2x1 and V2y1 is larger than Vref/4, and outputs a low-level output Ncx when the difference is smaller than Vref/4. The differential comparator Cmpy outputs a high-level output Ncy when the difference between V2x1 and V2y1 is larger than −Vref/4, and outputs a low-level output Ncy when the difference is smaller than −Vref/4.

In addition, when the control signal Nglt is switched from high level to low level at time T4, the output levels of the outputs Ncx and Ncy from the differential comparators Cmpx and Cmpy are held as data Ndx and Ndy by the latches Ltx and Lty.

Here, logical data D1 resulting from the current conversion is 1 when the data Ndx is high, and the logical data D1 is 0 when the data Ndx is low and the data Ndy is high, and the logical data D1 is −1 when the data Ndy is low. The logical data D1 is also stored by the data retention/switch control unit 32, and the control signal Nglt is switched back to high level at time T5.

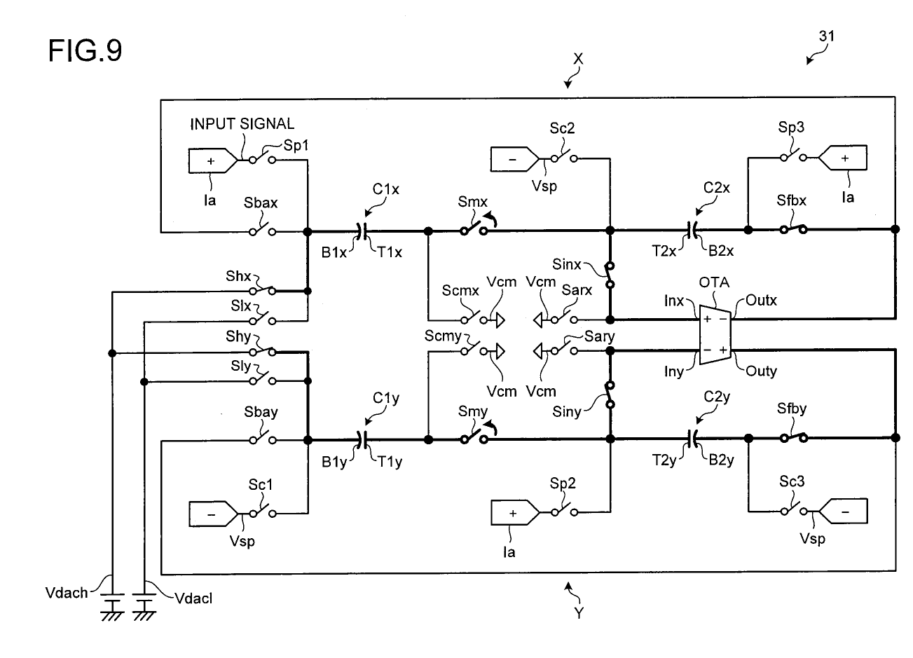

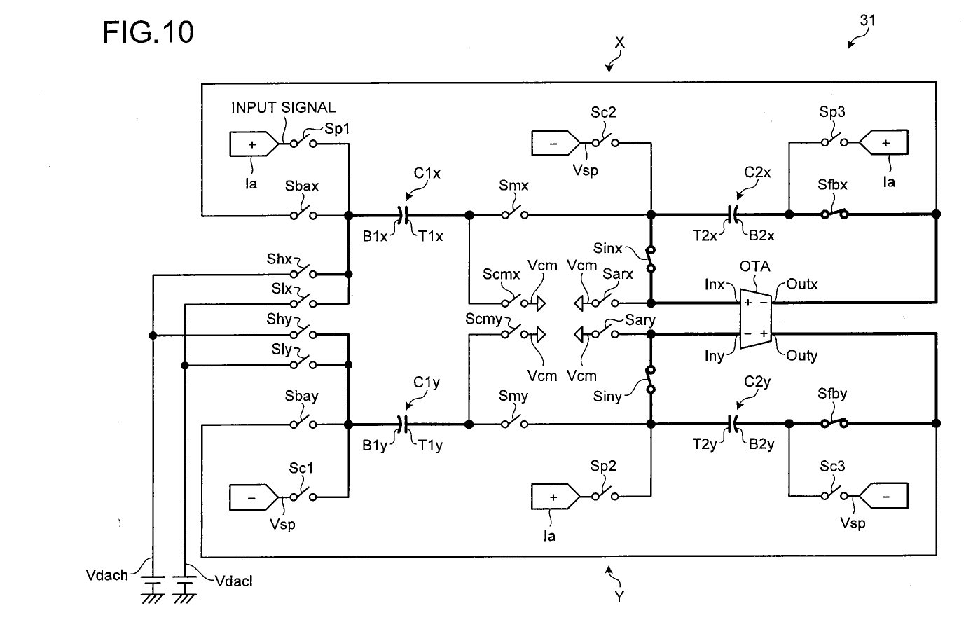

Subsequently, when the control signals for the switches Smx and Smy are switched to low level as illustrated in FIG. 3, the switches Smx and Smy are turned OFF as illustrated in FIG. 9. When the control signals for the switches Shx and Shy are switched to low level, the switches Shx and Shy are turned OFF as illustrated in FIG. 10.

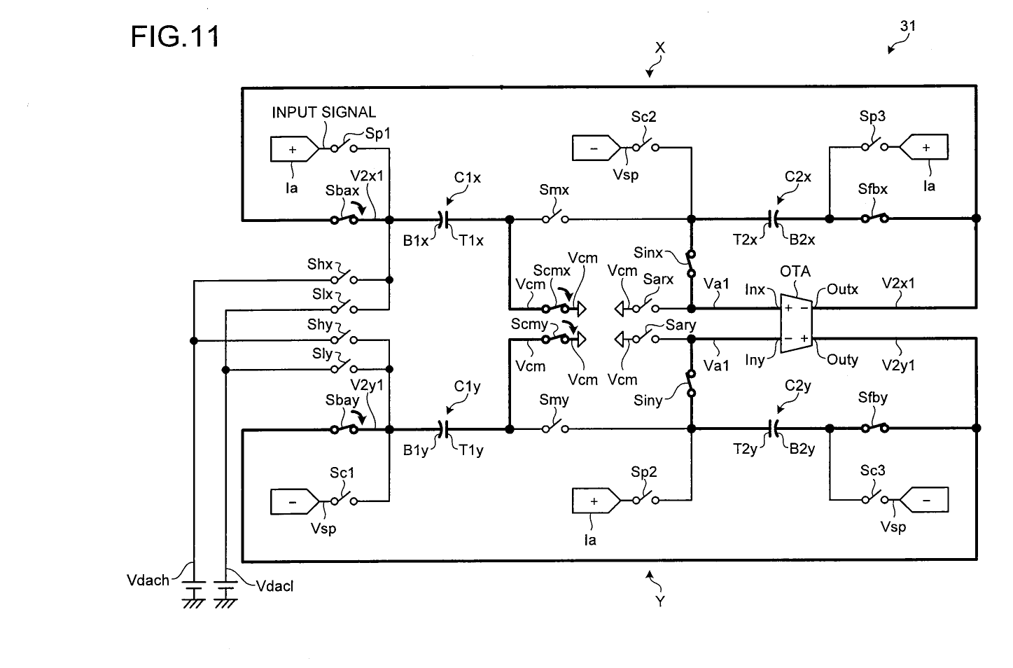

Subsequently, when the control signals for the switches Sbax, Sbay, Scmx, and Scmy are switched to high level as illustrated in FIG. 3, the switches Sbax, Sbay, Scmx, and Scmy are turned ON as illustrated in FIG. 11.

At this point, charge corresponding to C(Vcm−V2x1) is copied and stored in the first capacitor C1x and charge corresponding to C(Vcm−V2y1) is stored in the third capacitor C1y.

In addition, charge corresponding to C(Va1−V2x1) is stored in the second capacitor C2x, and charge corresponding to C(Va1−V2y1) is stored in the fourth capacitor C2y.

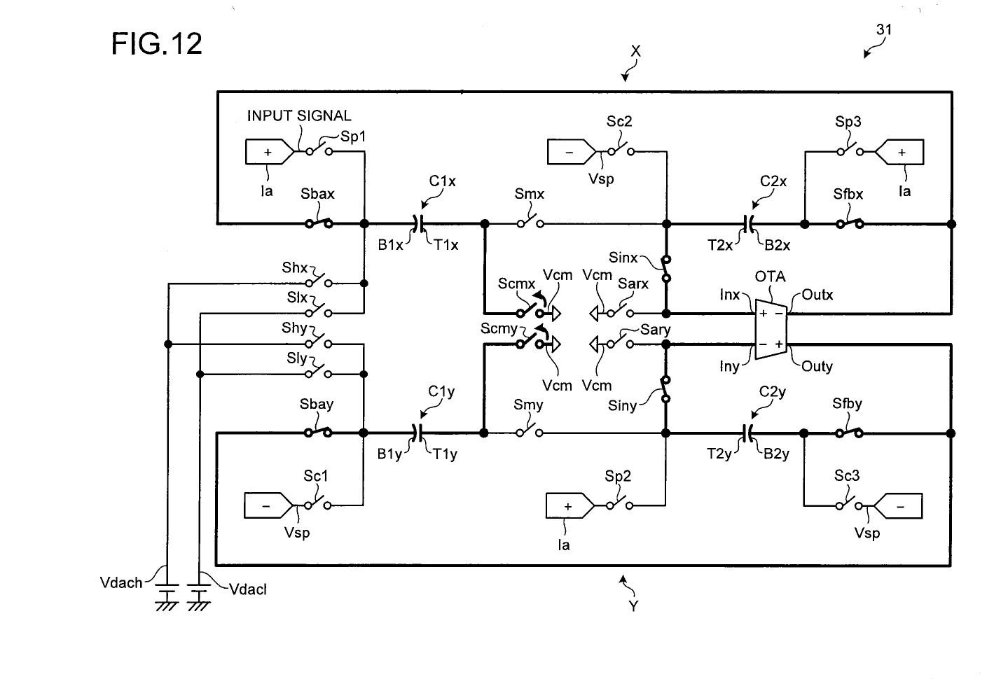

Subsequently, when the control signals for the switches Scmx and Scmy are switched to low level at time T6 as illustrated in FIG. 3, the switches Scmx and Scmy are turned OFF as illustrated in FIG. 12 and the charges in the first capacitor C1x and the third capacitor C1y are held.

Note that, according to Equation (6) and Equation (7), the charges in the first capacitor C1x, the third capacitor C1y, the second capacitor C2x, and the fourth capacitor C2y are C[−2(Vin−Vsp)], C[2(Vin−Vsp)], C[Va1−Vcm−2(Vin−Vsp)], and C[Va1−Vcm+2(Vin−Vsp)], respectively.

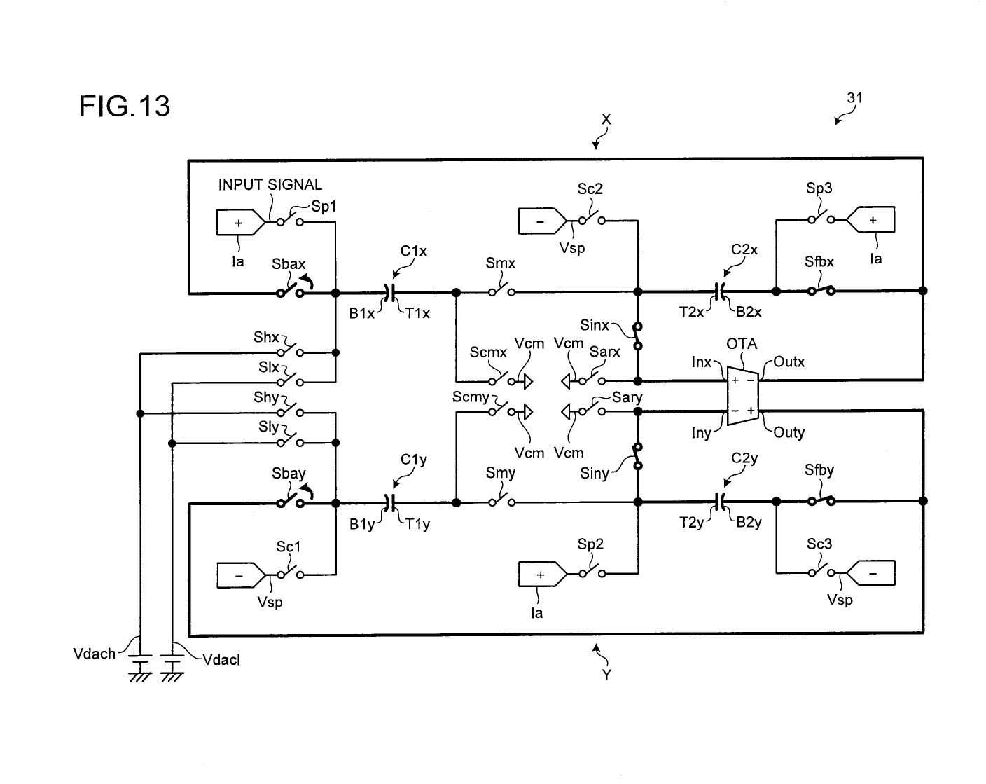

Subsequently, after the control signals for the switches Sbax and Sbay are switched to low level as illustrated in FIG. 3 and the switches Sbax and Sbay are thus turned off as illustrated in FIG. 13, switching dependent on the logical data D1 described above is conducted.

The switching is conducted by the data retention/switch control unit 32. If the logical data D1 is 1, the switches Shx and Sly are turned ON to apply the control voltage Vdach to the lower electrode B1x of the first capacitor C1x and apply the control voltage Vdac1 to the lower electrode B1y of the third capacitor C1y.

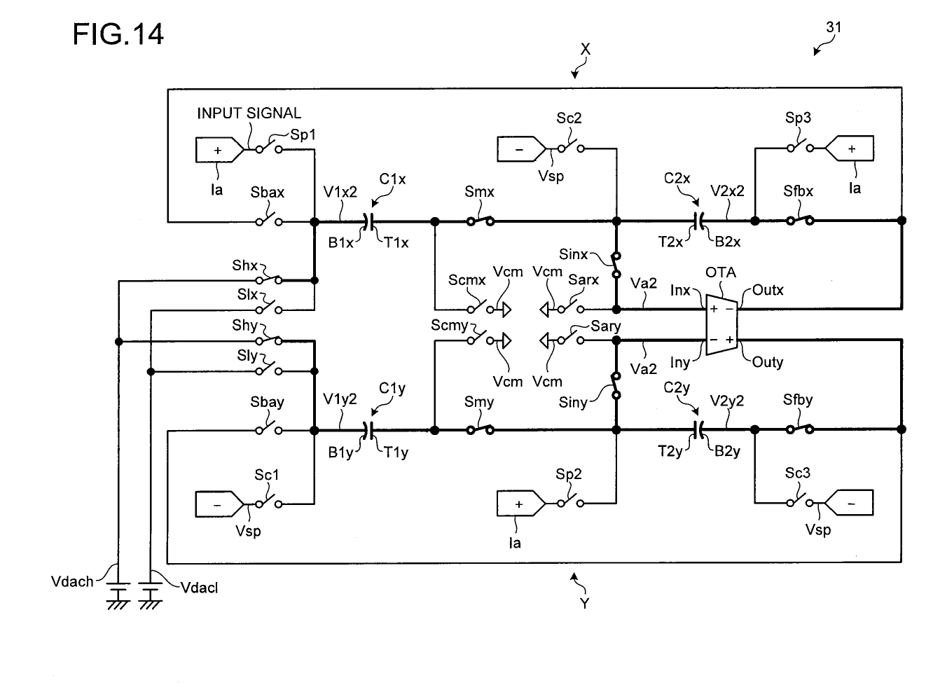

If the logical data D1 is 0, the switches Shx and Shy are turned ON to apply the control voltage Vdach to the lower electrode B1x of the first capacitor C1x and apply the control voltage Vdach to the lower electrode B1y of the third capacitor C1y as illustrated in FIG. 14.

If the logical data D1 is −1, the switches Slx and Shy are turned ON to apply the control voltage Vdac1 to the lower electrode B1x of the first capacitor C1x and apply the control voltage Vdach to the lower electrode B1y of the third capacitor C1y.

During the period in which the switching dependent on the logical data D1 is conducted, the control signals for the switches Smx and Smy are switched to high level as illustrated in FIG. 3 so that the switches Smx and Smy are also turned ON as illustrated in FIG. 14.

As a result, the charge stored in the first capacitor C1x is transferred to the second capacitor C2x and the charge stored in the third capacitor C1y is transferred to the fourth capacitor C2y.

Here, the control voltage Vdach is represented by Vcm+Vref/2 and the control voltage Vdac1 is represented by Vcm−Vref/2. The voltage of the lower electrode B1x of the first capacitor C1x is represented by V1x2, the voltage of the lower electrode B1y of the third capacitor C1y is represented by V1y2, the voltage of the lower electrode B2x of the second capacitor C2x is represented by V2x2, and the voltage of the lower electrode B2y of the fourth capacitor C2y is represented by V2y2. In addition, the voltage of the non-inverting input Inx and the inverting input Iny of the operational amplifier OTA is represented by Va2.

Then, at time T7 illustrated in FIG. 3, charge corresponding to C(Va2−V1x2) is stored in the first capacitor C1x and charge corresponding to C(Va2−V1y2) is stored in the third capacitor C1y. In addition, charge corresponding to C(Va2−V2x2) is stored in the second capacitor C2x and charge corresponding to C(Va2−V2y2) is stored in the fourth capacitor C2y.

Since the sum of the charges in the first capacitor C1x and the second capacitor C2x and the sum of the third capacitor C1y and the fourth capacitor C2y are maintained at time T6 and time T7 according to the law of charge conservation, the following equations are satisfied:

C[−2(Vin−Vsp)]+C[Va1−Vcm−2(Vin−Vsp)]=C(Va2−V1x2)+C(Va2−V2x2) Equation (8),

C[2(Vin−Vsp)]+C[Va1−Vcm−2(Vin−Vsp)]=C(Va2−V1y2)+C(Va2−V2y2) Equation (9).

The difference between Equation (8) and Equation (9) is:

8C(Vsp−Vin)=C(V1x2−V1y2)+C(V2x2−V2y2) Equation (10).

Modification of Equation (10) results in:

V2x2−V2y2=8(Vin−Vsp)−(V1x2−V1y2) Equation (11).

Equation (11) shows that, as a result of the switching, the difference between the voltage V2x2 and the voltage V2y2 is equal to subtracting the difference between the voltage V1x2 and the voltage V1y2 from eight times the difference between the input voltage Vin and the reference voltage Vsp.

Thus, the difference voltage between the inverted output Outx and the non-inverted output Outy is obtained by adding/subtracting the offset to eight times the difference (Vin−Vsp) from the input voltage.

Note that (V1x2−V1y2) is (Vdach−Vdacl)=Vref if the logical data D1 is high, (Vdach−Vdach)=0 if the logical data D1 is 0, and (Vdacl−Vdach)=−Vref if the logical data D1 is −1.

Equation (11) can thus be modified as follows:

V2x2−V2y2=8(Vin−Vsp)−D1*Vref Equation (12).

Furthermore, since the operational amplifier OTA is controlled so that the average of the voltage V2x2 and the voltage V2y2 becomes Vcm,

(V2x2+V2y2)/2=Vcm Equation (13) is satisfied.

Thus, combination of Equation (13) with Equation (12) described above results in:

V2x2=Vcm+0.5[8(Vin−Vsp)−2*D1*Vref] Equation (14); and

V2y2=Vcm−0.5[8(Vin−Vsp)−2*D1*Vref] Equation (15).

Note that the differential comparator Cmpx outputs a high-level output Ncx when the difference between V2x2 and V2y2 is larger than Vref/4, and outputs a low-level output Ncx when the difference is smaller than Vref/4.

The differential comparator Cmpy outputs a high-level output Ncy when the difference between V2x2 and V2y2 is larger than −Vref/4, and outputs a low-level output Ncy when the difference is smaller than −Vref/4. When the control signal Nglt is switched from high level to low level at time T7 as illustrated in FIG. 3, the output levels of the outputs Ncx and Ncy from the differential comparators Cmpx and Cmpy are held as data Ndx and Ndy by the latches Ltx and Lty.

Here, logical data D2 resulting from the current conversion is 1 when the data Ndx is high, and the logical data D2 is 0 when the data Ndx is low and the data Ndy is high, and the logical data D2 is −1 when the data Ndy is low. The logical data D2 is also stored by the data retention/switch control unit 32, and the control signal Nglt is switched back to high level at time T8.

Furthermore, as a result of repeating the switchings conducted at time T5, time T6, time T7, and time T8 to obtain logical data D3, D4, D5, . . . Dn subsequently to the logical data D1 and D2 obtained so far that can be obtained by repeating resampling and comparison of input signals, n-bit cyclic A/D conversion can be performed.

The logical data D1 to Dn can be combined by the following Equation (16) similarly to typical pipeline ADC and cyclic ADC to obtain a digital value Dout corresponding to an input analog value.

$$\begin{matrix}{D}_{out} = {2}^{- 1} {D}_{1} + {2}^{- 2} {D}_{2} + … + {2}^{- n} {D}_{n} \\ = {\sum }_{k = 1}^{n} {2}^{- k} {D}_{k} .\end{matrix} \qquad Equation ( 16 )$$

As described above, according to the ADC 30 according to the embodiment, an input signal is amplified fourfold at the first cyclic A/D conversion and the amplified input signal is sequentially amplified twofold at the second and subsequent cyclic A/D conversions. With the ADC 30, the S/N ratio in sampling conducted at time T2 is the same as that of a typical ADC in the related art that performs cyclic A/D conversion by amplifying an input signal twofold ever time including the first time and the second and subsequent times. With the ADC 30 of the embodiment, however, since the signal quantity at time T5 is four times the original signal quantity in contrast to twice the original quantity with the configuration of the related art, the S/N ratio after time T5 is higher than that in the related art.

Furthermore, the number of capacitors included in the ADC according to the embodiment is four that is the minimum required number for sequentially amplifying an input signal twofold and allowing fully-differential operation. Hence, according to the ADC of the embodiment, it is possible to improve the S/N ratio while suppressing an increase in the circuit size.

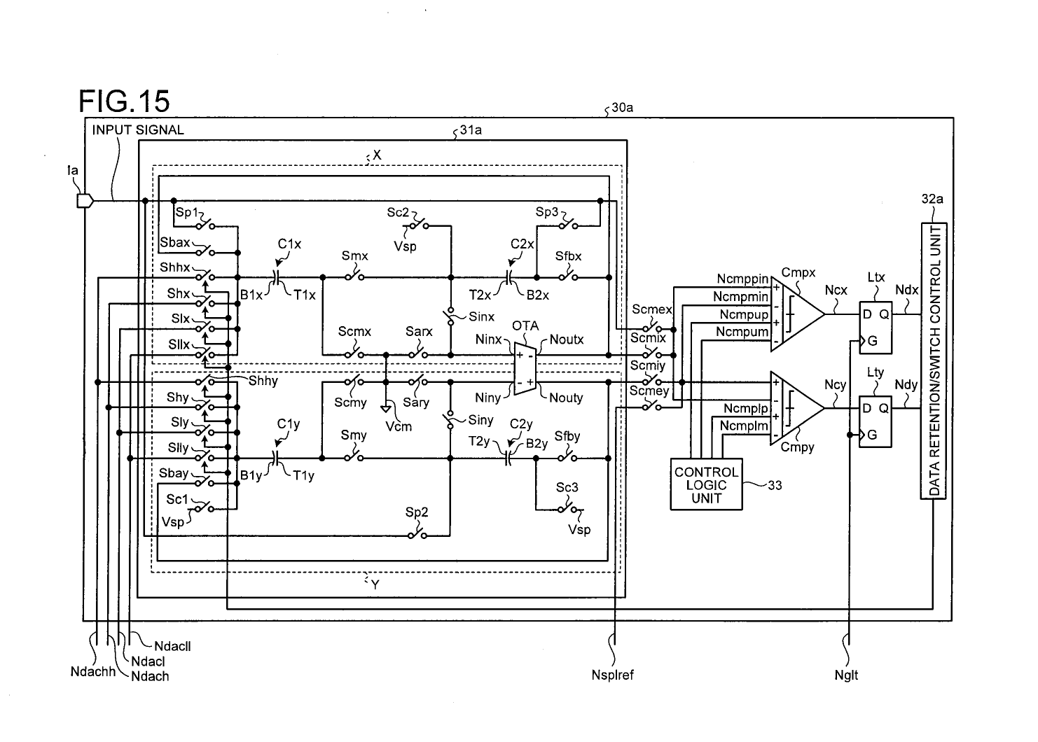

Note that the circuit configuration of the ADC 30 illustrated in FIG. 2 is only an example. Here, an example of a circuit configuration of an ADC 30a according to a modified example of the embodiment will be described with reference to FIG. 15. FIG. 15 is an explanatory diagram illustrating the example of the circuit configuration of the ADC 30a according to the modified example of the embodiment.

Here, components of the ADC 30a illustrated in FIG. 15 that are the same as those illustrated in FIG. 2 will be designated by the same reference numerals as those in FIG. 2 and the description thereof will not be repeated.

As illustrated in FIG. 15, the ADC 30a according to the modified example is configured such that four control voltages Ndachh, Ndach, Ndacl, and Ndacll can be applied to lower electrodes B1x and B1y of a first capacitor C1x and a third capacitor C1y included in an amplifier/subtractor 31a.

The four control voltages Ndachh, Ndach, Ndacl, and Ndacll are generated by a data retention/switch control unit 32a. The voltages Ndachh, Ndach, Ndacl, and Ndacll are applied to the lower electrodes B1x and B1y of the first capacitor C1x and the third capacitor C1y according to switching control on switches shhx, shx, slx, sllx, shhy, shy, sly, and slly by the data retention/switch control unit 32a. In addition, the voltage Vin is applied to Ncmppin of the differential comparators Cmpx and Cmpy and the voltage Vsplref is applied to Ncmpmin thereof.

The ADC 30a further includes a control logic unit 33 configured to control the reference voltages input to the differential comparators Cmpx and Cmpy. The control logic unit 33 can apply voltages to Ncmpup and Ncmpum so that the potential difference between Ncmpup and Ncmpum becomes Vref/4 and voltages to Ncmplp and Ncmplm so that the potential difference between Ncmplp and Ncmplm becomes −Vref/4.

For amplifying an input signal, the ADC 30a sequentially compares the input signal by the differential comparators Cmpx and Cmpy twice to measure the input signal with a resolution of 2 bits before the first amplification.

The ADC 30a then amplifies the input signal fourfold at the first amplification and subtract a predetermined value generated on the basis of data of the result of the second comparison conducted by the differential comparators Cmpx and Cmpy before the amplification from the input signal before the amplification. After the first amplification and the subtraction process, the switchings conducted at time T5, time T6, time T7, and time T8 described above are repeated.

As described above, with the ADC 30a, the number of types of voltages that can be applied to the lower electrodes B1x and B1y of the first capacitor C1x and the third capacitor C1y is four. As a result, the ADC 30a can conduct any of seven subtraction processes on an amplified input signal, which can further lower the voltage range of signals output by the operational amplifier OTA. With the ADC 30a, the guaranteed output voltage range of the operational amplifier OTA is smaller.

Alternatively, three signal lines may be used to apply voltages for the subtraction processes to the lower electrodes of the first capacitor C1x and the third capacitor C1y, and the voltage applied to one of the signal lines may be varied with time. In this case, the voltage applied to one signal line is varied with time on the basis of 2-bit data obtained by the second comparison conducted in advance. Note that the switching operations of the switches other than switches for applying voltages to the three signal lines are similar to those for the ADC 30a. According to such configuration, it is also possible to lower the voltage range of signals output from the operational amplifier OTA similarly to the ADC 30a illustrated in FIG. 15.

Note that a bias applied to each ADC 30, 30a for a subtraction process described in the embodiment can be generated by a circuit combining a resistive DAC (digital to analog converter) and a buffer amplifier, which is merely an example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An analog-to-digital converter comprising:
a comparator configured to compare an analog signal voltage output from a fully-differential operational amplifier including a non-inverting input, an inverting input, an inverted output, and a non-inverted output with a predetermined threshold and convert the voltage to digital data;
a first amplifier circuit configured to store electric charge corresponding to a signal having a phase reverse to that of an input signal to be converted by the comparator in each of a pair of capacitors during a first period and transfer the charge from one of the pair of capacitors to the other via the non-inverting input and the inverted output of the operational amplifier during a second period to amplify the reversed phase signal twofold; and
a second amplifier circuit configured to store electric charge corresponding to the input signal in each of a pair of capacitors during the first period and transfer the charge from one of the pair of capacitors to the other via the inverting input and the non-inverted output of the operational amplifier during the second period to amplify the input signal twofold.

2. The analog-to-digital converter according to claim 1, further comprising a supply unit configured to supply control voltages for suppressing voltages of signals output from the inverted output and the non-inverted output within a predetermined range to the first amplifier circuit and the second amplifier circuit on the basis of the digital data.

3. The analog-to-digital converter according to claim 2, wherein
the control voltages include two types of control voltages, and
the supply unit selects one of three combinations, in which one of the two types of the control voltages is supplied to each of the first amplifier circuit and the second amplifier circuit, on the basis of the digital data indicating a result of last conversion conducted by the comparator, and supplies the selected one combination of the control voltages to the first amplifier circuit and the second amplifier circuit.

4. The analog-to-digital converter according to claim 2, wherein
the control voltages include four types of control voltages, and
the supply unit selects one of seven combinations, in which one of the four types of the control voltages is supplied to each of the first amplifier circuit and the second amplifier circuit, on the basis of the digital data indicating a result of last two conversions conducted by the comparator, and supplies the selected one combination of the control voltages to the first amplifier circuit and the second amplifier circuit.

5. The analog-to-digital converter according to claim 2, wherein
the control voltages include two types of control voltages and one type of control voltage whose voltage value is changeable, and
the supply unit selects one of seven combinations, in which one of the two types of the control voltages and the one type of the control voltage is supplied to each of the first amplifier circuit and the second amplifier circuit, on the basis of the digital data indicating results of last two conversions conducted by the comparator, and supplies the selected one combination of the control voltages to the first amplifier circuit and the second amplifier circuit.

6. The analog-to-digital converter according to claim 1, wherein
the pair of capacitors included in the first amplifier circuit have an equal capacitance, and
the pair of capacitors included in the second amplifier circuit have an equal capacitance.

7. The analog-to-digital converter according to claim 6, wherein
the capacitors included in the first amplifier circuit and the capacitors included in the second amplifier circuit have an equal capacitance.

8. The analog-to-digital converter according to claim 1, wherein the first amplifier circuit and the second amplifier circuit are symmetric with the operational amplifier therebetween.

9. The analog-to-digital converter according to claim 1, comprising an amplifier/subtractor including the first amplifier circuit and the second amplifier circuit, and configured to output the analog signal obtained by amplifying the input signal and subtracting a predetermined value therefrom, wherein
the amplifier/subtractor amplifies the input signal fourfold during a period in which a first cyclic analog-to-digital conversion is conducted, and sequentially amplifies the input signal twofold during a period in which second and subsequent cyclic analog-to-digital conversions are performed.

10. A solid-state imaging device comprising:
a pixel unit in which a plurality of photoelectric conversion devices configured to perform photoelectric conversion on incident light and store a conversion result are arranged in a matrix; and
an analog-to-digital converter configured to convert analog pixel signals input from the photoelectric conversion devices to digital data, wherein
the analog-to-digital converter includes:
a comparator configured to compare an analog signal voltage output from a fully-differential operational amplifier including a non-inverting input, an inverting input, an inverted output, and a non-inverted output with a predetermined threshold and convert the voltage to digital data;
a first amplifier circuit configured to store electric charge corresponding to a signal having a phase reverse to that of an input signal to be converted by the comparator in each of a pair of capacitors during a first period and transfer the charge from one of the pair of capacitors to the other via the non-inverting input and the inverted output of the operational amplifier during a second period to amplify the reversed phase signal twofold; and
a second amplifier circuit configured to store electric charge corresponding to the input signal in each of a pair of capacitors during the first period and transfer the charge from one of the pair of capacitors to the other via the inverting input and the non-inverted output of the operational amplifier during the second period to amplify the reversed phase signal twofold.
